(19) United States
(12) Patent Application Publication
(10) Pub. No.: US 2024/0331632 A1
(43) Pub. Date: Oct. 3, 2024

(54) ARRAY SUBSTRATE AND DISPLAY DEVICE

(71) Applicant: Japan Display Inc., Tokyo (JP)

(72) Inventors: Kenji HARADA, Tokyo (JP); Hideyuki TAKAHASHI, Tokyo (JP); Tetsuo MORITA, Tokyo (JP); Masahiro KUBOTA, Tokyo (JP)

(21) Appl. No.: 18/614,807

(22) Filed: Mar. 25, 2024

(30) Foreign Application Priority Data
Mar. 27, 2023 (JP) 2023-049936

(51) Int. Cl. G09G 3/3233; H10K 59/131

(52) U.S. Cl. CPC G09G 3/3233; H10K 59/131; G09G 2300/0842; G09G 2310/08

(57) ABSTRACT

To effectively inhibit corrosion of a connecting terminal in an EL display, an array substrate includes a plurality of light emitting elements that are regularly arrayed, a scanning circuit that supplies the plurality of light emitting elements with at least a first scanning signal and a second scanning signal, and a plurality of connection terminals that are connected to the scanning circuit by a plurality of connection lines. The plurality of connection terminals include two adjacent connection terminals, an inverting circuit is interposed in at least one of two connection lines that connect the two adjacent connection terminals with the scanning circuit, and a same logic period in which output signals or input signals of the two adjacent connection terminals both have high potential or low potential in one scanning period is longer than a different logic period, in one scanning period.

### CROSS-REFERENCE TO RELATED APPLICATION

The present application claims priority from Japanese application JP2023-049936 filed on Mar. 27, 2023, the content of which is hereby incorporated by reference into this application.

### BACKGROUND OF THE INVENTION

### 1. Field of the Invention

The present the present invention relates to an array substrate and an image display device.

### 2. Description of the Related Art

WO2016/093483 A1 describes that dummy terminals are inserted between terminals formed on the FPC connected to the flexible organic EL display so as to increase the distances between the terminals, for the purpose of preventing corrosion of the terminals having a large potential difference, such as VGH and VGL, and VSS and VDD, and the valley patterns connected to the terminals (see particularly FIG. 22B).

### SUMMARY OF THE INVENTION

The invention disclosed in the present application has various aspects, and a summary of representative of those aspects is as follows.

(1) An array substrate includes a plurality of light emitting elements that are regularly arrayed, a scanning circuit that supplies the plurality of light emitting elements with at least a first scanning signal and a second scanning signal, and a plurality of connection terminals that are connected to the scanning circuit by a plurality of connection lines. The plurality of connection terminals include two adjacent connection terminals, an inverting circuit is interposed in at least one of two connection lines that connect the two adjacent connection terminals with the scanning circuit, and a same logic period in which output signals or input signals of the two adjacent connection terminals both have high potential or low potential in one scanning period is longer than a different logic period in which output signals or input signals of the two adjacent connection terminals have different potentials from each other, the one is high potential and the other is low potential, in one scanning period.

(2) In the array substrate according to (1), the different logic period is shorter than a period obtained by dividing the one scanning period by a number of scanning lines.

(3) In the array substrate according to (1) or (2), a difference between the number of the inverting circuits interposed in the connection line for one of the two adjacent connection terminals and a number of the inverting circuits interposed in the connection line for the other connection terminal is an odd number.

(4) In the array substrate according to any one of (1) to (3), a length of the connection wiring from the scanning circuit to the inverting circuit is shorter than a length of the connection wiring from the inverting circuit to the connection terminal.

(5) An image display device includes the array substrate according to any one of (1) to (4) and a driver circuit connected to at least a part of the plurality of connection terminals of the array substrate.

### BRIEF DESCRIPTION OF THE DRAWINGS

FIG. 1 is a schematic plan view of an array substrate according to a preferred embodiment of the present invention;

FIG. 2 is a circuit diagram showing a pixel circuit formed in an image area of the array substrate;

FIG. 3 is a timing chart of a start signal, a reset signal, and scanning signals in one scanning period;

FIG. 4 is a timing chart of signals applied to a start signal line, a reset signal line, a scanning signal line, and a scanning signal line in one scanning period;

FIG. 5 is a schematic plan view of the array substrate according to another embodiment of the present invention;

FIG. 6 is a timing chart of signals applied to a start signal line, a reset signal line, a scanning signal line, and a scanning signal line in one scanning period according to the other embodiment of the present invention; and

FIG. 7 is a diagram illustrating an example of an image display device using the array substrate according to the embodiment described above.

### DETAILED DESCRIPTION OF THE INVENTION

According to the findings of the applicant, connection lines incorporated into an image display device, such as an organic EL display, is required to be as compact as possible. At this time, as described in WO2016/093483A1, if a dummy terminal is provided between the terminals in order to prevent the corrosion of the terminals and the lines having a large potential difference, the FPC for the connection lines is increased in size. If the terminals and the wire pattern are miniaturized so as to reduce the connection lines in size, the distances between the terminals and the wire patterns are reduced even if the dummy terminal is provided, and thus corrosion is likely to occur.

In view of the circumstances described above, the applicant has completed the present invention. The present invention can effectively inhibit corrosion of a connecting terminal in an EL display. Additionally, the present invention can effectively inhibit corrosion of wire pattern in an EL display.

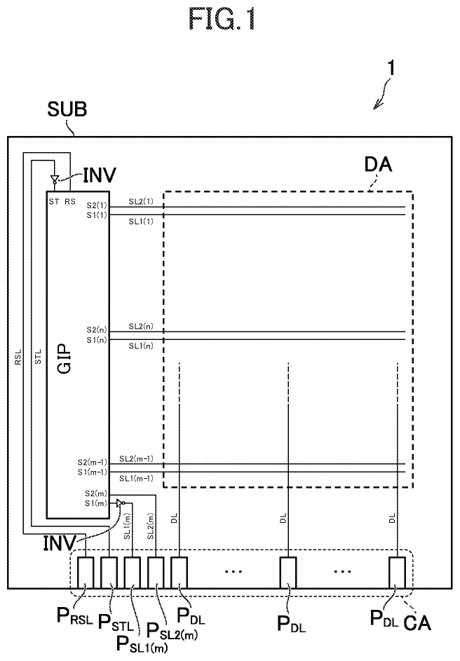

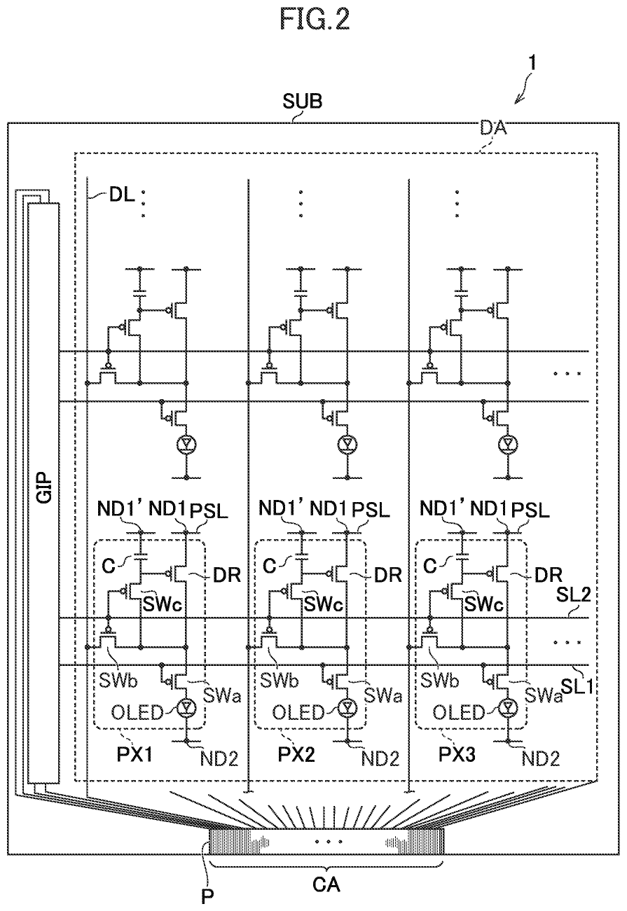

FIG. 1 is a schematic plan view of an array substrate 1 according to the preferred embodiment of the present invention, and FIG. 2 is a circuit diagram showing an example of a pixel circuit formed in an image area DA of the array substrate 1.

The array substrate 1 is a member connected to an appropriate driver circuit and incorporated in a device, thereby functioning as an image display device. The array substrate 1 constitutes a so-called dot matrix type flat panel display in which light emitting elements are regularly arrayed in a matrix on a planar substrate SUB. In the present embodiment, the light emitting element is an organic EL element, and the image display device configured using the array substrate 1 is an organic EL display.

The array substrate 1 is used in a lower surface light emission type organic EL display using an active matrix driving system. The array substrate 1 is an insulating substrate SUB, such as a glass substrate, including the image area DA, in which a plurality of light emitting elements are arrayed in a matrix and light emission brightness of each light emitting element is controlled so as to form an image, and a GIP (in-panel gate driver). A connection area CA is provided on the lower edge of the substrate SUB in FIG. 1. In the connection area CA, connection pads for electrically connecting the array substrate 1 to other devices are disposed.

The GIP is a so-called scanning circuit that outputs a vertical scanning signal to the pixel circuit formed in the image area DA. As will be described later, a set of two scanning signals are output for the pixel circuit used in the present embodiment, the set of two scanning signals are referred to as a scanning signal S1 and a scanning signal S2, per one scanning line. A set of two scanning signal lines extending from the GIP to the image area DA so as to transmit the scanning signals S1 and S2 to the pixel circuit are referred to as scanning signal lines SL1 and SL2. The last set of scanning signals S1 and S2 extending from the GIP is allocated for monitoring and is not used for displaying images. As such, when the number of sets of scanning signals that are output from the GIP is m, the vertical resolution of the image area DA is (m−1).

In the following, when the vertically arranged sets of scanning signals S1 and S2 are distinguished, numbers are assigned such that the first scanning signal in the scanning period shown in the top of FIG. 1 is assigned 1, the last scanning signal assigned for monitoring shown in the bottom of FIG. 1 is assigned m. The numbers in the vertical direction are written in parentheses, such as scanning signal S1(1) and scanning signal S2(m). The scanning signal lines corresponding to the respective scanning signals are also described with the numbers in parentheses in the vertical direction, such as the scanning signal line SL1(1) and the scanning signal line SL2(m). When the numbers in the vertical direction are not specifically distinguished, the numbers are simply described without parentheses, such as the scanning signal S1, the scanning signal S2, the scanning signal line SL1, and the scanning signal line SL2.

A plurality of data signal lines DL extend from the image area DA and are connected to the connection pads P individually provided in the connection area CA. The data signal line DL provides each pixel in the image area DA with a voltage value of luminance to be emitted by the light emitting element. The number of the data signal lines DL is equal to the horizontal resolution of the image area DA.

The connection pad P is a terminal for electrically connecting the array substrate 1 with other members, and is formed wider than other lines, such as signal lines formed on the substrate SUB, and eventually exposed without being sealed. The other members include an FPC (flexible printed circuit board), for example, and are connected to the connection pad by soldering or FOG (film on glass) mounting using an ACF (anisotropic conductive film). As will be described later, the connection pad P is also connected to other than the data signal line DL, and in the following, an index is attached to the reference symbol to specify which signal line is connected to the connection pad P. For example, a connection pad shown as P_{DL} is connected to a data signal line DL. When it is not distinguished whether a connection pad is connected to the signal line, the connection pad P is simply described without adding an index.

The GIP receives a start signal ST indicating a starting timing of scanning in the vertical direction from the outside and a reset signal RS resetting the internal state of the GIP. The input positions of the start signal and the reset signal RS of the GIP are in the vicinity of the scanning signal lines SL1(1) and SL2(1) to be scanned first, and are the upper parts of the GIP shown in FIG. 1. As such, the start signal line STL and the reset signal line RSL connected to the GIP extend along the side of the GIP opposite to the image area DA in parallel and are connected to the connection pad P_{STL} and the connection pad P_{RSL} of the connection area CA. The last vertical scanning signals S1(m) and S2(m) output from the GIP are also respectively connected to the connection pad P_{SL1(m)} and the connection pad P_{SL2(m)} through the scanning signal lines SL1(m) and SL2(m).

In the array substrate 1 according to the present embodiment, an inverting circuit INV is interposed in the vicinity of the GIP of the start signal line STL and the scanning signal line SL1(m) so as to invert the logic of the signal. The inverting circuit INV may be directly formed on the substrate SUB at the same time of forming the GIP on the substrate SUB. Alternatively, a semiconductor chip incorporating an inverting circuit may be mounted on the substrate SUB by a so-called COG (chip on glass) method.

FIG. 2 shows a circuit diagram of three adjacent pixels PX1 to PX3 as a part of the pixel circuits formed in the image area DA of the array substrate 1. Similarly to FIG. 1, FIG. 2 shows that the array substrate 1 has a substrate SUB, and the image area DA, the GIP, and the connection pad P formed in the connection area CA are disposed on the substrate SUB. In the array substrate 1 according to the present embodiment shown in FIGS. 1 and 2, the GIP is disposed only on the left side, which is one side of the image area DA, although the GIP may be disposed on the right side on the opposite or may be disposed on both sides.

In the present embodiment, the pixels PX1 to PX3 form triplets each constituted by three pixels PX1 to PX3 arranged in the horizontal direction and emit RGB light, although whether to form a triplet or to form a quartet or more may be freely determined depending on whether the image display device using the array substrate 1 is a monochrome display, a full color display, a three primary color display, or a four primary color display.

In the image area DA, the scanning signal lines SL1 and SL2 are formed in the horizontal direction and alternately arrayed in the vertical direction. A capacitor C is disposed corresponding to each of the pixels PX1 to PX3. Further, switching transistors SWa, SWb and SWc and a driving transistor DR are disposed corresponding to each of the pixels PX1 to PX3, and are wired as shown in FIG. 2. In this example, the switching transistors SWa, SWb and SWc and the driving transistor DR are top-gate type p-channel thin film transistors.

The data signal lines DL and the power supply lines PSL are formed in the image area DA. Each of the data signal lines DL extends in the vertical direction and arrayed in the horizontal direction. Each of the power supply lines PSL extends in the vertical direction and arrayed in the horizontal direction, for example.

An organic EL element OLED serving as a light emitting area is formed for each of pixels PX1 to PX3. The organic EL element OLED is patterned with a material corresponding to the emission colors of the pixels PX1 to PX3, and is sealed to prevent degradation. If the image display device using the array substrate 1 uses a color filter, the organic EL elements OLED may uniformly emit white light.

The driving transistor DR, the switching transistor SWa, and the organic EL element OLED are connected in series in this order between a first power supply terminal ND1 and a second power supply terminal ND2. In this example, the power supply terminal ND1 is a high-potential power supply terminal, and the power supply terminal ND2 is a low-potential power supply terminal. The gate of the switching transistor SWa is connected to the scanning signal line SL1. The switching transistor SWb is connected between the video signal line DL and the drain of the driving transistor DR, and the gate thereof is connected to the scanning signal line SL2. The switching transistor SWc is connected between the drain and the gate of the driving transistor DR, and the gate thereof is connected to the scanning line SL2. The capacitor C is connected between the gate of the driving transistor DR and the constant potential terminal ND1′. In this example, the constant potential terminal ND1′ is connected to the power supply terminal ND1.

The processes and materials for forming the pixel circuits described above on the substrate SUB and the arrangement and shapes of the components of the pixel circuits are well known and thus will not be described herein.

When the array substrate 1 is used as an image display device to display an image, the scanning signal lines SL2 are sequentially scanned, for example. That is, the pixels PX1 to PX3 are selected on a line-by-line basis. In a selection period over which one of the rows is selected, write operations are executed on the pixels PX1 to PX3 included in the selected row. In a non-selection period over which such a row is not selected, display operations are executed on the pixels PX1 to PX3 included in the non-selected row.

During the selection period over which the pixels PX1 to PX3 included in one of the rows are selected, the GIP outputs a scanning signal for opening the switching transistors SW1, i.e., a scanning signal for bringing switching transistors SWa to a non-conducting state as a voltage signal to the scanning signal line SL1 to which the selected pixels PX1 to PX3 are connected. Subsequently, the GIP outputs a scanning signal for closing the switching transistors SWb and SWc, i.e., a scanning signal for bringing the switching transistors SWb and SWc to a conducting state as a voltage signal to the scanning signal line SL2 to which the selected pixels PX1 to PX3 are connected. In this state, a video signal is fed as a current signal (write current) through the video signal line DL, so as to set the gate-to-source voltage of the driving transistor DR at a value corresponding to the magnitude of the video signal. Subsequently, the GIP outputs a scanning signal for opening the switching transistors SWb and SWc as a voltage signal to the scanning signal line SL2 to which the selected pixels PX1 to PX3 are connected, and then outputs a scanning signal for closing the switching transistors SWa as a voltage signal to the scanning signal line SL1 to which the selected pixels PX1 to PX3 are connected. This terminates the selection period.

In the non-selection period following the selection period, the switching transistors SWa are kept closed, and the switching transistors SW2 and SW3 are kept open. In the non-selection period, a drive current flows through each organic EL element OLED at magnitude corresponding to the gate-to-source voltage of the driving transistor DR. The organic EL element OLED emits light at luminance corresponding to the magnitude of the drive current. In other words, the drive current and the video signal are almost equal in magnitudes, and thus it is possible to make the organic EL element OLED to emit light at luminance corresponding to the magnitude of the video signal.

The array substrate 1 of the present embodiment employs the pixel circuit shown in FIG. 2, although any pixel circuit can be used if the pixel circuit can control the magnitude of the drive current according to the magnitude of the video signal. For example, the pixel circuit may employ a configuration to use a voltage signal instead of a current signal as the video signal supplied from the video signal line DL to the pixel circuit. Further, an n-channel thin film transistor may be used as the switching transistors SWa, SWb and SWc and the driving transistor DR instead of the p-channel thin film transistor.

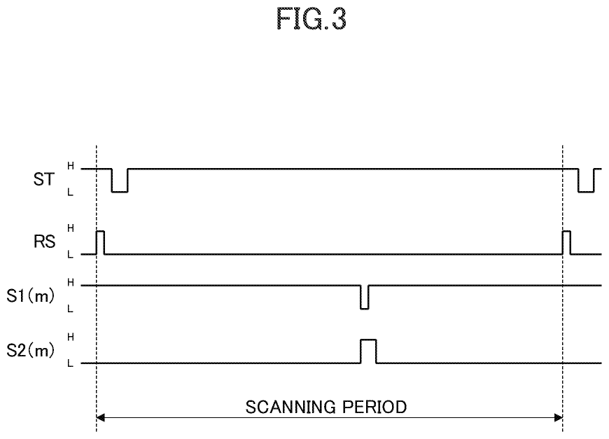

FIG. 3 is a timing chart of the start signal ST, the reset signal RS, the scanning signal S1(m), and the scanning signal S2(m) in one scanning period. As can be seen from FIG. 1, the signal lines (start signal line STL, reset signal line RSL, scanning signal line SL1(m), and scanning signal line SL2(m)) for transmitting those signals and the connection pads (connection pad P_{STL}, connection pad P_{RSL}, connection pads P_{SL1(m)}, and connection pad P_{SL2(m)}) are disposed adjacently on the substrate SUB.

As can be seen from FIG. 3, the reset signal RS receives a very short pulse-like high signal relative to the scanning period at the beginning of the scanning period, and remains a low signal for the other periods. The start signal ST receives a very short pulse-like low signal relative to the scanning period immediately after the high signal of the reset signal RS, and remains a high signal for the other period. The scanning signal S1(m) is sequentially scanned from the first scanning line, and when the last mth timing arrives, outputs a very short pulse-like low signal relative to the scanning period, and remains a high signal for the other period. The scanning signal S2(m) outputs a very short pulse-like high signal relative to the scanning period when the last mth timing arrives, and remains a low signal for the other period.

The period in which the start signal ST, the reset signal RS, the scanning signal S1(m), and the scanning signal S2 output pulse-like signals is very short relative to the scanning period, and is usually 1% or less of the scanning period. As such, the start signal ST and the scanning signal S1(m) are in a high state and the reset signal RS and the scanning signal S2(m) are in a low state for substantially the entire duration of the scanning period. In this regard, the term “substantially the entire duration” refers to a period longer than at least half of a specific period (here, a scanning period).

Returning to FIG. 1, when the potentials having the same logic levels as the start signal ST, the reset signal RS, the scanning signal S1(m), and the scanning signal S2(m) are applied to the respective signal lines (start signal line STL, reset signal line RSL, scanning signal line SL1(m), and scanning signal line SL2(m)) and the connection pads P (connection pad P_{STL}, connection pad P_{RSL}, connection pad P_{SL1(m)}, and connection pad P_{SL2(m)}), the adjacent start signal line STL and the reset signal line RSL receive potentials having different logic levels over substantially the entire scanning period, and thus a potential difference is generated between the high potential and the low potential. Similarly, the connection pad P_{STL} and the connection pad P_{RSL} adjacent to each other receive potentials having different logic levels over substantially the entire duration of the scanning period, and thus a potential difference is generated between the high potential and the low potential.

The same applies between the connection pad P_{RSL} and the connection pad P_{SL1(m)}, between the scanning signal line SL1(m) and the scanning signal line SL2(m), and between the connection pad P_{SL1(m)} and the connection pad P_{SL2(m)}. These signal lines and the connection pads P receive potentials having different logic levels between adjacent ones over substantially the entire duration of the scanning period, and thus a potential difference is generated between the high potential and the low potential.

As described above, when the potentials having different logic levels are applied to adjacent signal lines or connection pads P, an electric field is generated between the adjacent signal lines or connection pads P, and corrosion due to so-called electromigration or electrochemical migration occurs. This causes a failure such as a short circuit or a disconnection, thereby shortening the life of the product. The influence of the corrosion is greater when the structures of the signal line or the connection pad P are more precise, their sizes are smaller, and the distances between them are shorter. As such, if the distance between the signal lines and the distance between the connection pads P are broadened in order to retard the corrosion, it will hinder the miniaturization of the product.

In view of the above, as shown in FIG. 1, the array substrate 1 according to the present embodiment includes an inverting circuit INV interposed therein near the GIP of the start signal line STL and the scanning signal line SL1(m), and the logic is inverted before and after the inverting circuit INV.

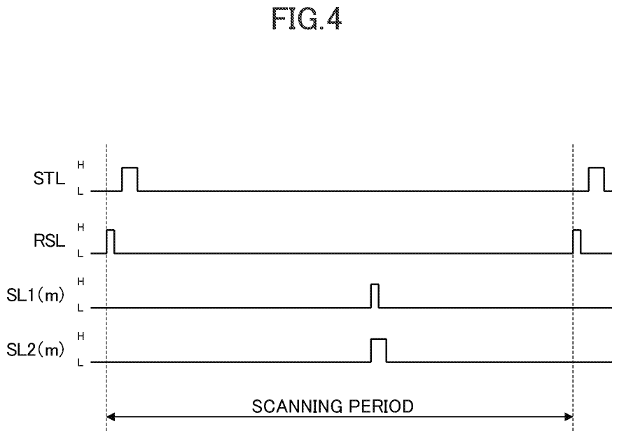

FIG. 4 is a timing chart of signals applied to the start signal line STL, the reset signal line RSL, the scanning signal line SL1(m), and the scanning signal line SL2(m) in one scanning period. The logic of the signal is inverted in the start signal line STL and the scanning signal line SL1(m) before and after the interposed inverting circuit INV. As such, FIG. 4 shows the logic of the signal in the main section, that is, the section where the length of the signal line is longer before and after the inverting circuit INV. The signal logic in the connection pad P_{STL}, the connection pad P_{RSL}, the connection pad P_{SL1(m)}, and the connection pad P_{SL2(m)} coincides with the signal logic applied to the start signal line STL, the reset signal line RSL, the scanning signal line SL1(m), and the scanning signal line SL2(m), respectively.

As can be seen from FIG. 4, the signal logic of the start signal ST and the scanning signal S1(m) is inverted by the inverting circuit INV from the high state to the low state over substantially the entire duration of the scanning period. As such, the main section of the start signal line STL, the reset signal line RSL, the main sections of the scanning signal line SL1(m), and the scanning signal line SL2(m) have the same signal logic over substantially the entire duration of the scanning period. Accordingly, the start signal line STL, the reset signal line RSL, the scanning signal line SL1(m), and the scanning signal line SL2(m) are at the same potential between adjacent signal lines over substantially the entire duration of one scanning period, and no electric field is generated. For a small period of time in which a high-state pulse-like signal is applied, a potential difference occurs between adjacent signal lines and an electric field is generated. Such a period is usually less than 1% of one scanning period and is practically negligible. As such, a short circuit and a disconnection of the signal line due to the influence of the electric field can be virtually prevented.

The same applies to the connection pad P_{STL}, the connection pad P_{RSL}, the connection pad P_{SL1(m)}, and the connection pad P_{SL2(m)}, and the signal logic is the same for substantially the entire duration of one scanning period and no electric field is generated between the adjacent connection pads P. As such, a short circuit and a disconnection of the connection pad P due to the influence of the electric field can be also virtually prevented.

In the embodiment described above, the start signal line STL, the reset signal line RSL, the scanning signal line SL1(m), and the scanning signal line SL2(m) are adjacent to each other in this order, and the connection pad P_{STL}, the connection pad P_{RSL}, the connection pad P_{SL1(m)}, and the connection pad P_{SL2(m)} are adjacent to each other in this order. The inverting circuit INV is interposed in the start signal line STL and the scanning signal line SL1(m), and whereby the potentials of these signal lines and the connection pads P are in a low state over substantially the entire duration of one scanning period. However, it is clearly seen in principle that the present invention is not limited to such a combination in order to effectively prevent corrosion caused by an electric field between adjacent signal lines and connection pads P.

For example, in the embodiment described above, the inverting circuit INV is interposed in the start signal line STL and the scanning signal line SL1(m), although the present invention is not limited thereto, and the same advantages can be obtained if the inverting circuit INV is interposed in the reset signal line RSL and the scanning signal line SL2(m). In this case, the start signal line STL, the reset signal line RSL, the scanning signal line SL1(m), the scanning signal line SL2(m), the connection pad P_{STL}, the connection pad P_{RSL}, the connection pad P_{SL1(m)}, and the connection pad P_{SL2(m)} have high potentials for substantially the entire duration of one scanning period.

To express the above in a more generalized manner, assume a condition in which at least a plurality of connection terminals (connection pad P in the embodiment) are connected, by at least a plurality of connection lines (signal lines in the embodiment), to a scanning circuit (GIP in the embodiment), which provides first scanning signal and a second scanning signal, such as the scanning signals SL1 and SL2, that are of different logic for substantially the entire duration of one scanning period. When there are any two adjacent connection lines and any two adjacent connection terminals connected to the connection lines, if an inversion circuit INV is interposed in at least one of the two connection lines and the same logic period in which the potentials of these two connection lines and the two connection terminals are both high or low is longer than the different logic period in which the potentials of these two connection lines and the two connection terminals are different from each other, corrosion caused by the electric field between these connection lines and the connection terminals can be virtually prevented.

The different logic period is generally short enough as compared with one scanning period, although the different logic period occurs only when the vertical scanning signal is given or when the start signal ST and the reset signal RS are given, and thus the different logic period is shorter than the period obtained by dividing the one scanning period by the number of scanning lines.

In the adjacent connection lines (signal lines), when the section of the same logic over substantially the entire duration of one scanning period is longer, the corrosion caused by the electric field can be more advantageously prevented. In view of this, it is preferable that the length of the connection line from the scanning circuit (GIP) to the inverting circuit INV is shorter than the length from the inverting circuit INV to the connection terminal (connection pad P). As shown in the embodiment above, the inverting circuit INV is preferably provided in the vicinity of the GIP in the signal line in which the inverting circuit INV is interposed.

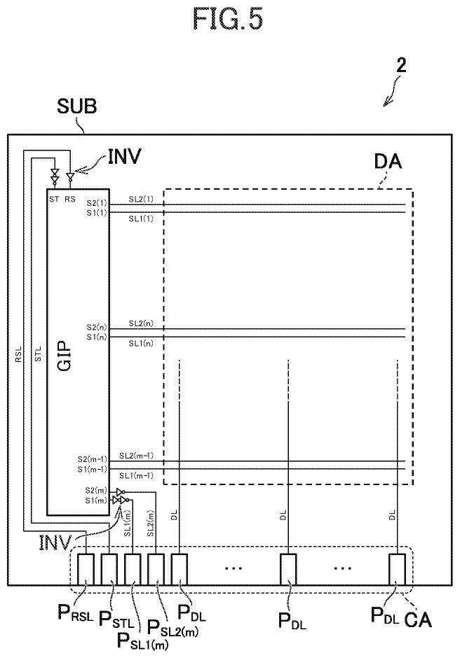

The number of the inverting circuits INV to be provided in two adjacent signal lines is not limited to one. FIG. 5 is a schematic plan view of an array substrate 2 according to another embodiment of the present invention. The array substrate 2 has the same configuration as the array substrate 1 of the embodiment described above except for the arrangement of the inverting circuit INV, and thus the same reference numerals are given to the common elements and the redundant description are omitted. The circuit diagram shown in FIG. 2 is employed to illustrate an example of a pixel circuit formed in the image area DA of the array substrate 2.

In some cases, an inverting circuit is interposed in the middle of the signal line so as to properly forming waveforms of rising edges and falling edges of a signal and stabilizing the logic of the signal, that is, the signal potential. In such a case, an inverting circuit may basically be interposed in all the signal lines transmitting the logic signal.

In the array substrate 2 shown in FIG. 5, the inverting circuits INV are interposed in all of the start signal line STL, the reset signal line RSL, the scanning signal line SL1(m), and the scanning signal line SL2(m). However, when the same number of inverting circuits INV are uniformly interposed in adjacent signal lines, for example, when one inverting circuit INV is interposed per signal line, the logic of the start signal ST, the reset signal RS, the scanning signal S1(m), and the scanning signal S2(m) shown in FIG. 3 is merely inverted. As such, the signals supplied to the adjacent signal lines and the connection pads P, for example, the start signal line STL and the reset signal line RSL, are logically different from each other over substantially the entire duration of the scanning period, and thus a potential difference occurs between the high potential and the low potential.

As shown in FIG. 5, when two inverting circuits INV are interposed in series in the start signal line STL and one inverting circuit INV is interposed in the reset signal line RSL, a signal of the same logic as the start signal ST is applied to the start signal line STL and a signal of the inverted logic of the reset signal RS is applied to the reset signal line RSL. As such, the signals applied to the main sections of the start signal line STL and the reset signal line RSL have the same logic over substantially the entire duration of the scanning period and no potential difference is generated. This virtually prevents the corrosion caused by the electric field.

More generally, the difference between the number of inverting circuits interposed in the connection line (signal line) for one of two adjacent connection terminals (connection pads) and the number of inverting circuits interposed in the connection line for the other connection terminal may be an odd number. Even if the signal logic of the signals entered into or output from the scanning circuit (GIP) for the two connection terminals and the connection lines is different over substantially the entire duration of the scanning period, the signal logic in the main section of the two connection terminals and the connection lines for transmitting the signal is the same, and thus the corrosion caused by the electric field is virtually prevented.

In the example shown in FIG. 5, the two adjacent connection terminals are the connection pad P_{RSL} and the connection pad P_{STL}, and one inverting circuit INV is interposed in the reset signal line RTL connected to the connection pad P_{RSL} and two inverting circuits INV are interposed in the start signal line STL connected to the connection pad P_{STL}. Accordingly, the difference in the number is one and is an odd number. The same relationship is applied to the connection pads P_{SL1(m)} and the connection pads P_{SL2(m)}, and also to the scanning signal line SL1(m) and scanning signal line SL2(m) connected thereto.

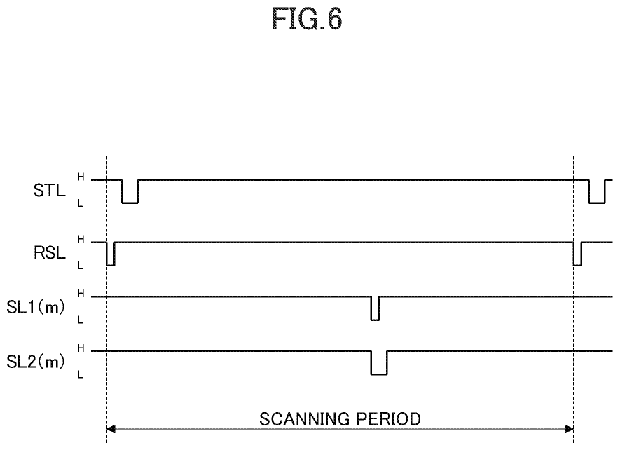

FIG. 6 is a timing chart of signals applied to the start signal line STL, the reset signal line RSL, the scanning signal line SL1(m), and the scanning signal line SL2(m) in one scanning period for the other embodiment. As compared with the example shown in FIG. 4, the logic of the signals is inverted as a whole, although it can be seen that all the signals are in a high state for substantially the entire duration of the scanning period and have the same logic, and thus a potential difference is not generated. As such, the array substrate 2 according to this embodiment is similar to the array substrate 1 according to the previous embodiment in that a short circuit and a disconnection of the signal line due to the influence of the electric field can be virtually prevented.

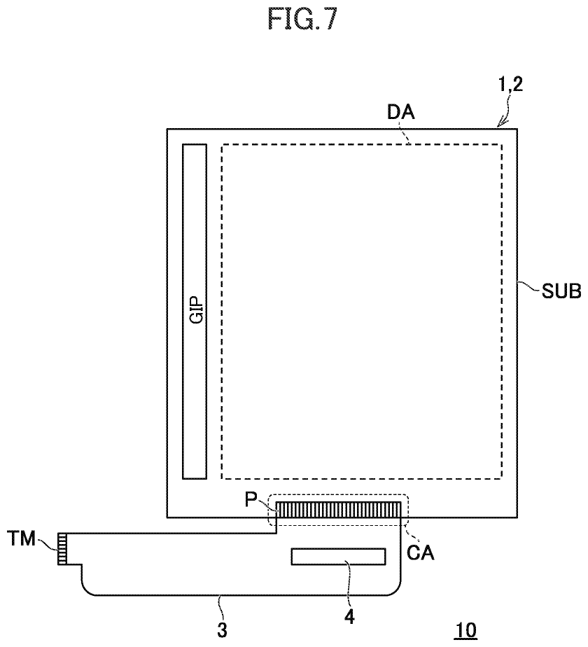

FIG. 7 is a diagram illustrating an example of the image display device 10 using the array substrate 1 or the array substrate 2 (hereinafter, referred to as array substrate 1, 2) according to the embodiment described above.

The image display device 10 is an organic EL display, and can be used in a portable device, such as a smart phone, a pad-type terminal, and a notebook PC, a television or a monitor, or a vehicle-mounted device and a facility-embedded device. The image display device 10 includes the connection pads P arranged in the connection area CA of the array substrate 1, 2 with the FPC 3 connected and fixed thereto using the FOG method.

The FPC 3 includes a terminal TM electrically connecting to a device incorporating the image display device 10 and an LSI 4 incorporating a driver circuit for driving the array substrate 1, 2. The driver circuit is electrically connected to the terminal TM, and receives information of an image to be displayed on the image area DA of the array substrate 1, 2 from a display control circuit, such as a graphics controller included in the embedded device.

The driver circuit is connected to the connection pad P formed in the connection area CA of the array substrate 1, 2, and outputs signals, such as a start signal ST, a reset signal RS, and a data signal, to the array substrate 1, 2 in synchronization with an appropriate scan cycle. When an odd number of inverting circuits INV are interposed in a signal line of the array substrate 1, 2, a signal of inverted logic is output as a signal corresponding to such a signal line.

The driver circuit is configured to receive a scanning signal S1(m) and a scanning signal S2(m) from the array substrate 1, 2. Upon receiving such signals, the driver circuit confirms that one scan has been completed and then outputs the start signal ST and the reset signal RS for the subsequent scan. If there is no input of the scanning signal S1(m) or the scanning signal S2(m) during the scanning period, the driver circuit may transmit an error signal to the embedded device. Alternatively, the scanning signal S1(m) and the scanning signal S2(m) may be used only for checking the quality of the array substrate 1, 2 at the time of manufacturing, and the driver circuit may ignore such signals or may not be connected to the connection pad P_{SL1(m)} and the connection pad P_{SL2(m)} to receive such signals. In any case, the driver circuit is electrically connected to at least a part of the connection terminals (connection pads P) of the array substrate 1, 2.

While there have been described what are at present considered to be certain embodiments of the invention, it will be understood that various modifications may be made thereto, and it is intended that the appended claims cover all such modifications as fall within the true spirit and scope of the invention.

What is claimed is:

1. An array substrate comprising:
a plurality of light emitting elements that are regularly arrayed;
a scanning circuit that supplies the plurality of light emitting elements with at least a first scanning signal and a second scanning signal; and
a plurality of connection terminals that are connected to the scanning circuit by a plurality of connection lines, wherein
the plurality of connection terminals include two adjacent connection terminals,
an inverting circuit is interposed in at least one of two connection lines that connect the two adjacent connection terminals with the scanning circuit, and
a same logic period in which output signals or input signals of the two adjacent connection terminals both have high potential or low potential in one scanning period is longer than a different logic period in which output signals or input signals of the two adjacent connection terminals have different potentials from each other, the one is high potential and the other is low potential, in one scanning period.

2. The array substrate according to claim 1, wherein
the different logic period is shorter than a period obtained by dividing the one scanning period by a number of scanning lines.

3. The array substrate according to claim 1, wherein
a difference between the number of the inverting circuits interposed in the connection line for one of the two adjacent connection terminals and a number of the inverting circuits interposed in the connection line for the other connection terminal is an odd number.

4. The array substrate according to claim 1, wherein
a length of the connection line from the scanning circuit to the inverting circuit is shorter than a length of the connection line from the inverting circuit to the connection terminal.

5. A display device comprising an array substrate and a driver circuit, wherein
the array substrate comprises:
a plurality of light emitting elements that are regularly arrayed;
a scanning circuit that supplies the plurality of light emitting elements with at least a first scanning signal and a second scanning signal; and
a plurality of connection terminals that are connected to the scanning circuit by a plurality of connection lines, wherein
the plurality of connection terminals include two adjacent connection terminals,
an inverting circuit is interposed in at least one of two connection lines that connect the two adjacent connection terminals with the scanning circuit,
a same logic period in which output signals or input signals of the two adjacent connection terminals both have high potential or low potential in one scanning period is longer than a different logic period in which output signals or input signals of the two adjacent connection terminals have different potentials from each other, the one is high potential and the other is low potential, in one scanning period, and
the driver circuit is connected to at least one of the plurality of connection terminals.
